(19) United States
(12) Patent Application Publication
(10) Pub. No.: US 2013/0070422 A1
(43) Pub. Date: Mar. 21, 2013

(54) ENCLOSURE-INTEGRATED HANDLE FEATURES FOR MOUNTING STORAGE DEVICES

(71) Applicants: John M. Dunham, Kechi, KS (US); Alan T. Pfeifer, Wichita, KS (US); Chen-Hsing Peng, Taoyuan City (TW)

(72) Inventors: John M. Dunham, Kechi, KS (US); Alan T. Pfeifer, Wichita, KS (US); Chen-Hsing Peng, Taoyuan City (TW)

(73) Assignee: LSI CORPORATION, Milpitas, CA (US)

(21) Appl. No.: 13/233,224

(22) Filed: Sep. 15, 2011

(51) Int. Cl. H05K 7/14; A47B 81/00; B23P 11/00; A47B 96/00

(52) U.S. Cl. 361/725; 312/319.1; 312/236; 29/428

(57) ABSTRACT

Systems and methods are hereby provided for enclosures having integrated handle features for storing one or more storage devices. The system includes a rigid frame and multiple bays. Each bay includes a body movably attached to the frame, wherein repositioning of the body with respect to the frame is restricted by at least one holding element of the frame to a limited range of motion. The body defines a receptacle for receiving and holding a storage device. Each bay also includes a lever arm rotatably attached to the frame, the lever arm comprising a cam surface to engage with the body and to move the body upon rotation of the lever arm. When the lever arm achieves a first position, the body engages the storage device with a communication channel, and when the lever arm achieves a second position, the body disengages the storage device from the communication channel.

### RELATED PATENTS

This patent is related to commonly owned U.S. patent application Ser. No. 13/116,818 entitled STORAGE DEVICE CARRIERS FOR ADAPTING A STORAGE DEVICE OF A FIRST SIZE TO A SLOT FOR A STORAGE DEVICE OF A SECOND SIZE which is hereby incorporated by reference.

### BACKGROUND

1. Field of the Invention

The invention relates generally to storage systems and more specifically relates to storage enclosures for housing storage devices.

2. Discussion of Related Art

Storage systems may be used to house a large number of storage devices (e.g., magnetic disks, optical drives, solid-state memory, etc.) and communicatively couple those storage devices with a computer system. Storage systems may comprise, for example, racks or other high density enclosures that comprise multiple drawers/blades, each drawer adapted to house multiple storage devices. Each drawer may be stored within the enclosure, and may be communicatively coupled with the computer system by use of a suitable backplane or cabling structure (e.g., a cable chain). The drawer itself may be opened to access the storage devices that it houses, and each storage device may be communicatively coupled with the drawer via a hardware connection residing, for example, on a printed circuit board of the drawer.

To restrain the motion of each storage device within the drawer, the drawer will typically include bays that are sized for a specific type of drive. The drive may, for example, be screwed into its respective bay, and may have a communication channel manually attached to it by a field technician. This is generally inconvenient and overly time-consuming for operators of the storage system.

To address these issues, the drive itself may be pre-mounted (e.g., with a screw or other device) onto a removable frame known as a “carrier” or Customer Replaceable Unit (CRU), and the CRU itself may be placed into a bay of the drawer to allow for faster replacement of the storage device. However, CRU's are undesirable for several reasons. First, CRU's add cost and weight to storage devices. Second, CRU's are often proprietary designs. This means that a storage system operator will be unable to “swap” a storage device from one proprietary storage system to another without first dismantling the CRU from the storage device (assuming the CRU can be removed in the first place). Third, because CRU's are typically proprietary and are delivered to customers in a state where they are already integrated with a storage device, it is generally not possible to replace a storage device for the storage system without ordering a new storage device and associated CRU from the supplier of the original storage system.

Thus it is an ongoing challenge to develop storage systems which allow for convenient replacement of storage devices and also do not require the use of CRU's.

### SUMMARY

The present invention solves the above and other problems, thereby advancing the state of the useful arts, by providing methods and systems for mounting storage devices to a storage enclosure without use of a tool or a CRU. The methods and systems include storage systems that have multiple bays for receiving storage devices (devoid of any CRU), each bay including an integrated handle feature capable of moving the bay within the enclosure and engaging a storage device within the bay with a communication channel of the enclosure. Thus, users may easily mount and dismount storage devices from the storage systems without a need for a CRU or tool.

In one aspect hereof, a storage enclosure for housing multiple storage devices is provided. The storage enclosure comprises a rigid frame and multiple bays mounted within the frame. Each bay comprises a body movably attached to the frame, wherein repositioning of the body with respect to the frame is restricted by at least one holding element of the frame to a limited range of motion at the enclosure. The body defines a receptacle for receiving and holding a storage device having dimensions matching a standardized form factor. Each bay further comprises a lever arm rotatably attached to the frame, the lever arm comprising a cam surface adapted to engage with the body of the bay and adapted to move the body with respect to the enclosure upon rotation of the lever arm. When the lever arm achieves a first rotational position, the body is adapted to engage the storage device with a communication channel of the enclosure. When the lever arm achieves a second rotational position, the body is adapted to disengage the storage device from the communication channel.

Another aspect hereof provides a method for utilizing such a system. The method includes identifying an enclosure comprising multiple bays. The method also includes selecting a bay of the enclosure comprising a body and further comprising a lever arm rotatably attached to the frame of the enclosure, the lever arm comprising a cam surface adapted to engage with the body of the bay and move the bay with respect to the enclosure upon rotation of the lever arm, wherein the body is movably attached to the frame, wherein repositioning of the body with respect to the frame is restricted by at least one holding element of the frame to a limited range of motion at the enclosure, wherein the body defines a receptacle for receiving and holding a storage device having dimensions matching a standardized form factor. The method also includes placing, within the receptacle of the bay, a storage device having dimensions matching the standardized form factor. Further, the method includes moving the lever arm to a first rotational position, displacing the body of the bay with respect to the enclosure, thereby engaging the storage device with a communication channel of the enclosure.

### BRIEF DESCRIPTION OF THE DRAWINGS

FIG. 1 is a block diagram of an exemplary storage system including drawers having multiple bays, each bay having an integrated handle in accordance with features and aspects hereof.

FIG. 2 is a perspective view of an exemplary bay having an integrated handle feature in accordance with features and aspects hereof.

FIGS. 3-4 are diagrams illustrating a top view of an exemplary body of a bay in accordance with features and aspects hereof.

FIG. 5 is a flowchart describing an exemplary method in accordance with features and aspects hereof to utilize a storage enclosure that includes integrated handle features.

FIGS. 6-7 are diagrams illustrating the action of a cam surface of an exemplary handle of a bay as the handle is rotated.

FIG. 8 is a diagram illustrating a perspective view of an exemplary bay comprising multiple additional features.

FIGS. 9-13 are diagrams illustrating a side view of an exemplary bay as a storage device is placed and secured within the bay.

### DETAILED DESCRIPTION OF THE DRAWINGS

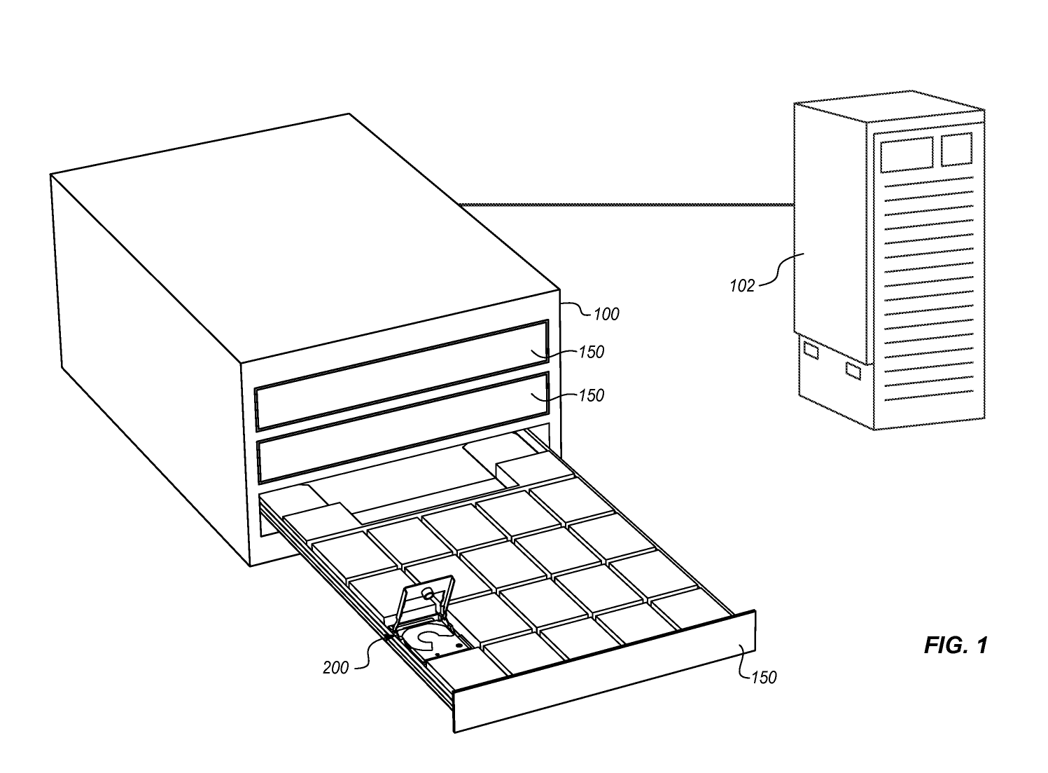

FIG. 1 is a block diagram of an exemplary storage system 100 including drawers 150 having multiple bays 200, each bay 200 having an integrated handle in accordance with features and aspects hereof According to FIG. 1, storage system 100 is communicatively coupled with host 102, and may perform data storage, retrieval, and/or backup operations for host 102 (e.g., an application, computer, processor, etc. having data processing needs). In this embodiment, storage system 100 is implemented as a high density, multi-drawer drive enclosure for rack-based storage. Each drawer 150 is operable to mount storage devices within bays 200. Storage system 100 may further comprise one or more controllers adapted to manage the operations of the storage devices. For example, a storage controller may implement a Redundant Array of Independent Disks (RAID) architecture among storage devices, may route Input/Output (I/O) requests to and from storage devices, and may perform other known functions appreciated by those having ordinary skill in the art. The storage devices mounted at bays 200 comprise any functional components for storing data. For example, the storage devices may comprise magnetic disks, optical drives, solid-state memory, etc.

Each drawer 150 of storage device 100 includes a rigid frame, and comprises multiple bays 200 mounted to the rigid frame. Drawers 150 may also be referred to as “blade drives” or “blade enclosures.” In some embodiments, a drawer 150 may further comprise motors (not shown) for automatically extending drawer 150 outward. Each drawer 150 may further optionally include a power supply (not shown) for powering storage devices located at bays 200. Drawers 150 include physical communication channels (not shown) that communicatively couple the storage devices located at bays 200 to a computer system such as host 102 (or other controlling devices).

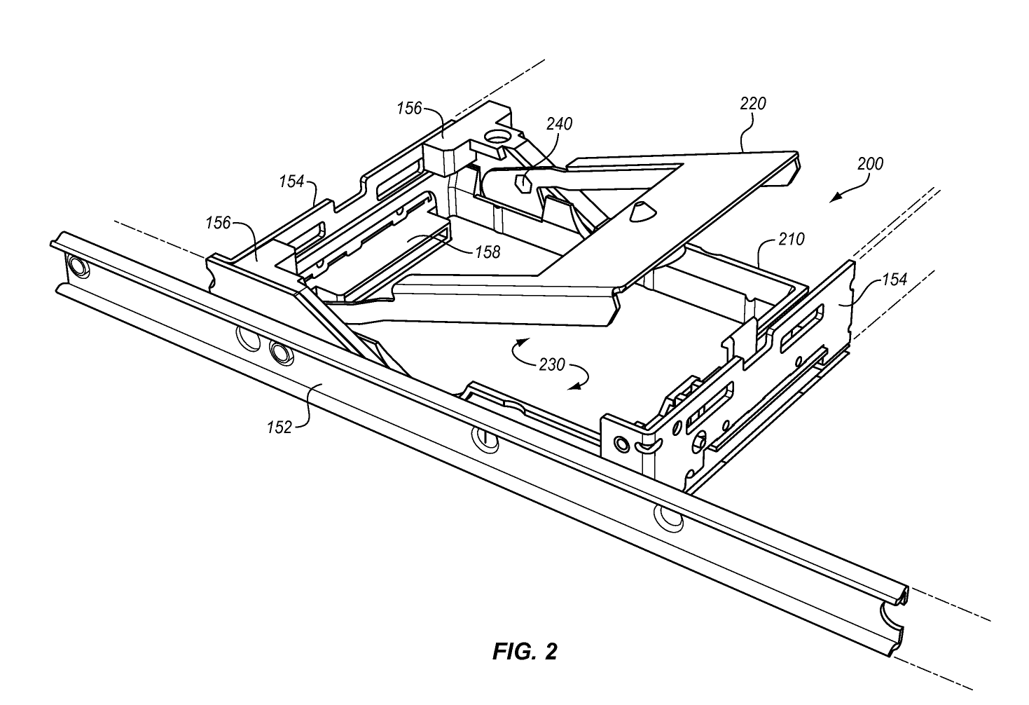

The bays 200 implemented at storage system 100 each include an integrated handle feature. Each bay 200 is adapted to receive a storage device compliant with a standard, defined form factor (e.g., a 2.5 inch or 3.5 inch form factor). A storage system operator may open the handle of a bay 200, place a storage device into the bay 200, and close the integrated handle to secure the storage device and communicatively couple it with storage system 100. The handle itself may slide the body of the bay forwards and backwards in order to facilitate the securement of the storage device, but does not detach bay 200 from the enclosure. Further details of bay 200 will be described with regard to FIG. 2. Assume, for this embodiment, that bay 200 resides within a drawer 150 or other storage enclosure having a rigid frame (i.e., a frame with rigid components).

FIG. 2 is a perspective view of a bay 200 having an integrated handle feature 220 in accordance with features and aspects hereof. According to FIG. 2, bay 200 comprises a bay body 210, which is movably coupled with respect to rigid frame elements 152-156 of a drawer (e.g., drawer 150 of FIG. 1). Body 210 has inner walls that define a receptacle 230 for receiving a storage device dimensioned according to a known form factor (e.g., a 2.5 inch form factor). Such a receptacle 230 may be dimensioned to receive the drive itself, and need not be dimensioned to receive a Customer Replaceable Unit (CRU) or other proprietary drive adapter. In one embodiment, to reduce the number of moving parts at bay 200, bay body 210 does not include a floor for receiving the storage device. Rather, the floor on which the storage device rests may be immovably integrated with any of rigid frame elements 152-156. Thus, when body 210 moves within bay 200, body 210 slides a storage device across the floor portion of the frame and onto a physical communication channel (i.e., electrical connector) 158 of drawer 150. Body 210 may also comprise additional features for receiving, holding, and aligning a storage device within bay 200.

In one embodiment, handle 220 of bay 200 is rotatably attached to one or more of frame elements 152-156 utilizing a pivot point 240. The method of rotatable attachment utilized at pivot point 240 may include, for example, the fixation of handle 220 about a cylindrical bolt extending from one of frame elements 152-156, a ratcheted rotatable mounting for handle 220, a bolt or rivet structure, or any other suitable mechanical hinging mechanism. As handle 220 is rotated about frame elements 152-156, features of handle 220 are adapted to engage with bay 200 and move body 210 with respect to frame elements 152-156 of drawer 150. For example, rotation of handle 220 may engage a cam surface to slide body 210 back and forth within bay 200 (as discussed in further detail below). Note that handle 220 does not disengage bay 200 from the drawer, but rather moves body 210 back and forth within bay 200. In another embodiment, a cam surface of handle 220 or a rack-and-pinion mechanism may engage with and move body 210. In one embodiment, when handle 220 occupies a downward, or “closed” position, the top of handle 220 lies flush with bay 200, and does not extend above the surface of bay 200.

In one exemplary embodiment, handle 220 normally forms a ceiling or top surface of bay 200 while in the closed position. This secures the storage device within bay 200. In this embodiment, when handle 220 is moved to the open position, body 210 shifts forward, and a user may replace the storage device from receptacle 230 without interference from handle 220.

Once a storage device has been placed into receptacle 230, handle 220 may be closed. Sliding body 210 (and hence receptacle 230) via handle 220 provides a significant benefit, as it allows a storage device to be dropped into an open receptacle 230 with minimal effort. At the same time, the sliding action of body 210 allows body 210 to move a storage device into position and engage it with physical communication channel 158 of drawer 150, thereby communicatively integrating the storage device into the storage system with a single smooth motion. Note that communication channel 158 may comprise any component for transmitting and/or receiving electrical signals (e.g., data, status, and instructions) directed to or from a storage device. For example, communication channel 158 may comprise a Serial Attached SCSI (SAS) adapter, Serial ATA (SATA) adapter, Universal Serial Bus (USB) adapter, ribbon cable, or other connector.

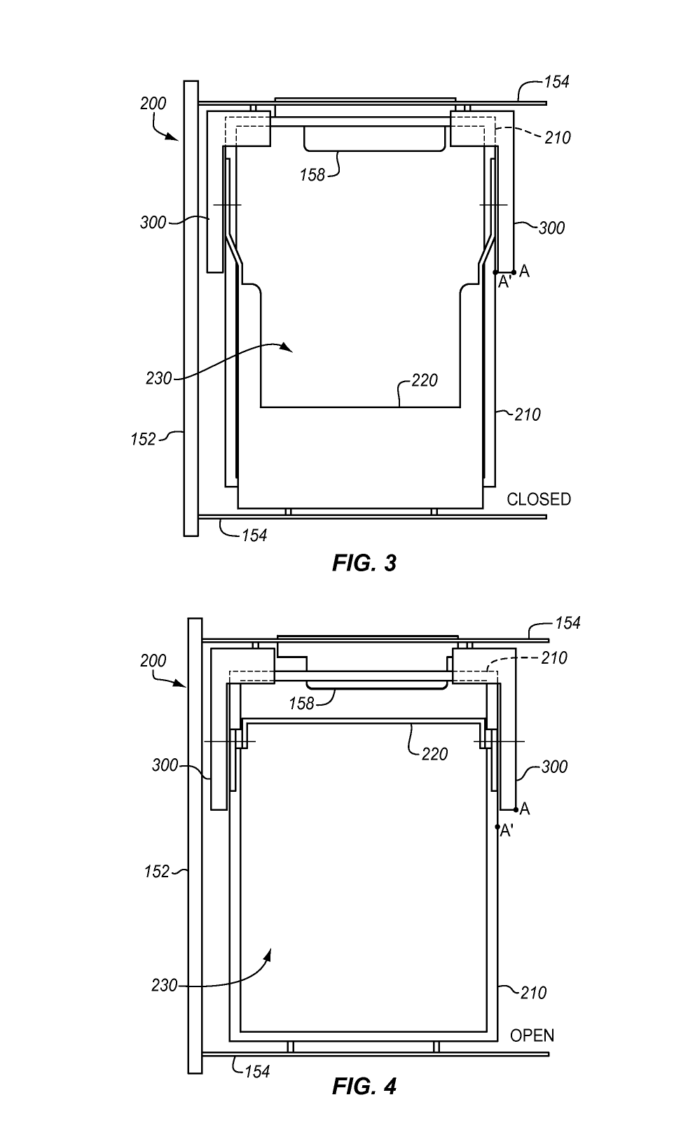

FIGS. 3-4 are diagrams illustrating a top view of an exemplary body 210 of a bay 200 in accordance with features and aspects hereof Body 210 is movable with respect to frame elements 152-156. However, the range of motion of body 210 is restricted to a limited set of positions by frame elements 152-156 of drawer 150. The specific frame elements that restrict the motion of body 210 may be referred to as holding elements, because they hold body 210 from exiting bay 200 and drawer 150. In this embodiment, holding elements 300 are partially hollowed-out versions of frame elements 156. Holding elements 300 allow body 210 to move forward and backward to a limited degree. However, the overall range of motion (and therefore the overall range of positions that body 210 may occupy) is limited by internal sidewalls of holding elements 300.

In FIG. 3, handle 220 is in the closed position, and body 210 is positioned as far back as is allowed by the geometry of holding elements 300. Sidewalls of holding elements 300 prevent body 210 from any further motion to the back. Note that in FIG. 3, a location at a holding element 300 (location A) lines up with a location at body 210 (location A′). In FIG. 4, a force is applied to body 210 as handle 220 is rotated to the open position, moving body 210 towards the front until the motion of body 210 is restrained by side walls of holding elements 300. Note that in FIG. 4, location A at holding element 300 and location A′ at body 210 no longer occupy the same forward/backward position, because body 210 has moved while frame elements 152-156 have not moved.

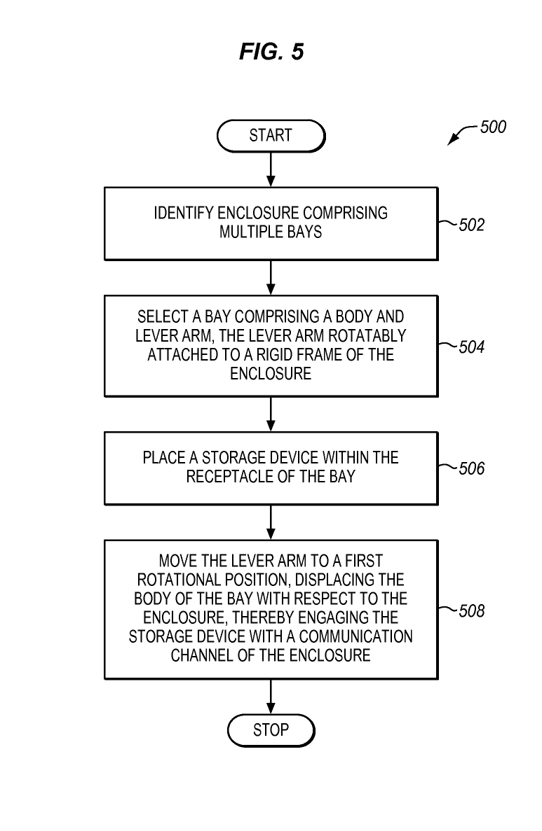

FIG. 5 is a flowchart describing an exemplary method 500 in accordance with features and aspects hereof to utilize a storage enclosure 100 that includes integrated handle features. The method of FIG. 5 may be operable in a storage system 100 such as described above with regard to FIGS. 1-4.

In step 502, a user identifies an enclosure comprising multiple bays. In step 504, the user selects a bay of the enclosure comprising a body and further comprising a lever arm rotatably attached to the frame of the enclosure. As noted above, the lever arm may comprise a cam surface (or other suitable means) adapted to engage with the body of the bay to move the bay with respect to the enclosure upon rotation of the lever arm. According to step 504, the selected body is movably attached to the frame, wherein repositioning of the body with respect to the frame is restricted by at least one holding element of the frame to a limited range of positions/motions at the enclosure. Further according to step 504, the selected body defines a receptacle for receiving and holding a storage device having dimensions matching a standardized form factor.

In step 506, the method comprises placing, within the receptacle of the bay, a storage device having dimensions matching the standardized form factor.

In step 508, the method further comprises moving the lever arm to a first rotational position, displacing the body of the bay with respect to the enclosure, thereby engaging the storage device with a communication channel of the enclosure and securing the storage device within the body of the bay.

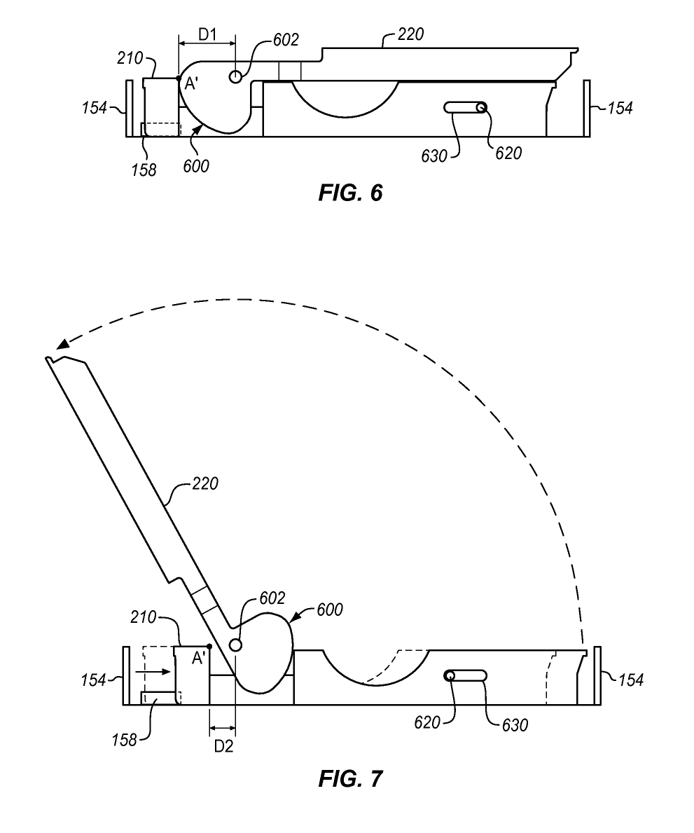

FIGS. 6-7 are diagrams illustrating the action of an exemplary cam surface 600 of a handle 220 of a bay as the handle is rotated. Both of FIGS. 6-7 illustrate a side view of a body 210 of a bay, and of handle 220 rotatably attached at pivot point 602 about frame elements 152-156 (not shown). In FIG. 6, handle 220 is in the closed position. In this position, the lateral distance between location A′ and the center of pivot point 602 is a distance D1. Additionally, while in the closed position, body 210 overlaps communication channel 158 used for coupling a storage device with storage system 100. Note that while handle 220 is in the closed position, cam surface 600 engages with a left border of body 210, pushing body 210 towards the left to mate a storage device to communication channel 158. The portion of body 210 that is engaged by cam surface 600 may have a depth or thickness that is different than the rest of body 210 to allow cam surface 600 to securely engage the body. In this embodiment, a holding element 620 keeps body 210 restricted to a limited range of motion with regard to bay 200. In particular, holding element 620 comprises a cylinder extending outward from frame element 152 (see FIG. 1) and into a cavity 630 of body 210. As cam surface 600 slides body 210 left and right (in the orientation of the figure), holding element 620 and cavity 630 combine to impose limits on the range of motion of body 210. A holding element 620 may exist along each side of body 210.

In FIG. 7, handle 220 is rotated into the open position. During rotation of handle 220, cam surface 600 disengages from a left portion of body 210 and engages a right portion of body 210, thereby pushing body 210 towards the right. Note that in this position, the distance between location A′ and the center of pivot point 602 is a distance D2, which in this embodiment is smaller than D1. Also note that communication channel 158 no longer substantially overlaps body 210. Thus, in the open position, bay 200 can receive a storage device without interference from communication channel 158. While cam surface 600 is depicted as extending below body 210, cam surface 600 need not do so. Furthermore, if cam surface 600 is designed to extend below body 210, then a portion of bay 200 may be “carved out” or removed in order to allow cam surface 600 to move freely without encountering resistance. In alternate embodiments, bay 200 may return handle 220 to a default (closed or open) position by use of a spring loaded element that applies leftward or rightward force to body 210. For example, the spring element may push body 210 in order to automatically close or open handle 220 when the user does not apply any force of their own.

FIG. 8 is a diagram illustrating a perspective view of an exemplary bay comprising multiple additional features. According to FIG. 8, bay 200 further comprises a catch 802 for keeping handle 220 securely in place when handle 220 engages in the closed position. Catch 802 may be a flexible prong extended from body 210, a pin for securing handle 220 to bay 200, a lock, or other suitable means for ensuring that handle 220 maintains a closed position. Another additional feature of bay 200 in this embodiment includes a spacer 804 such as a rubber stopper, that may be used to restrict the motion of a storage device within bay 200 and secure the storage device. Such a spacer 804 or other element at handle 220 may be used to ensure that a storage device within bay 200 does not move while handle 220 is in the closed position. Furthermore, in FIG. 8 handle 220 includes an additional heat sink 806 for cooling a storage device. Heat sink 806 may include, for example, a series of fins at a top surface, and a thermal coupling at a bottom surface, in order to dissipate heat generated by a storage device in the bay. Heat sink 806 may be removably or fixedly attached to handle 220, and may further extend upward from handle 220 or lay flush against handle 220.

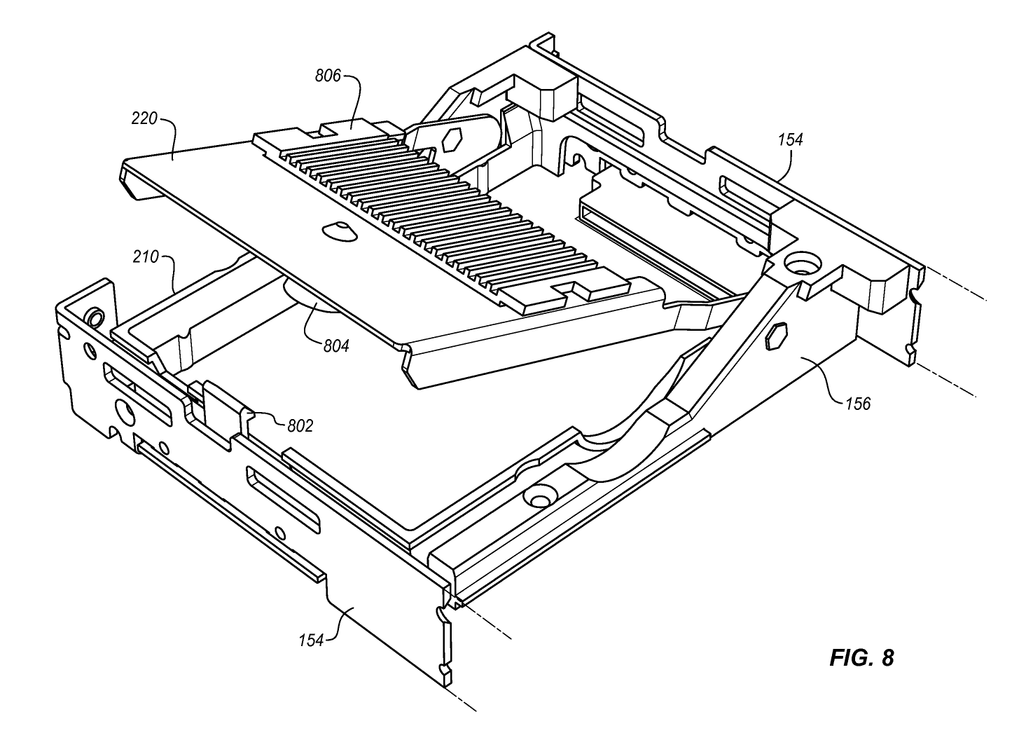

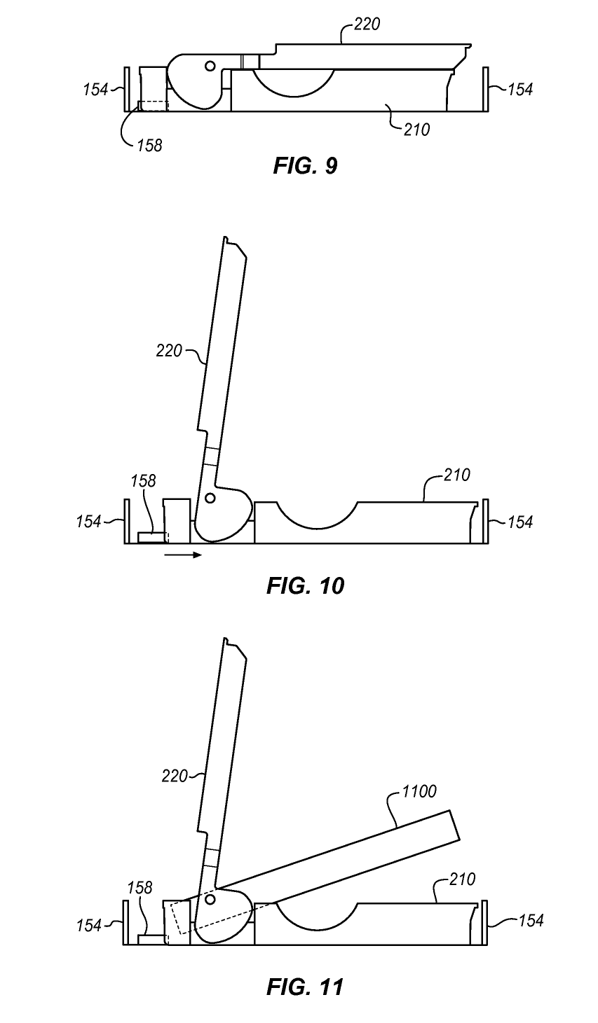

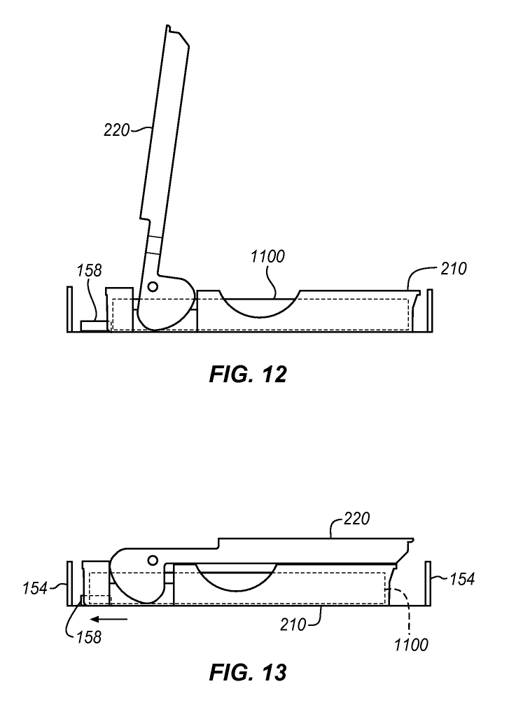

FIGS. 9-13 are diagrams illustrating a side view of a bay 200 as a storage device 1100 is placed and secured within the bay. In FIG. 9, handle 220 occupies the closed position. In this closed position. According to FIG. 10, handle 220 is placed in the open position. In the open position, body 210 of bay 200 does not intersect with communication channel 158 of drawer 150. In FIG. 11, storage device 1100 is inserted into a receptacle defined by body 210 while handle 220 is in the open position. In FIG. 12, storage device 1100 rests in the receptacle defined by body 210. In FIG. 13, handle 220 is placed in the closed position, sliding body 210 towards the left. As body 210 slides towards the left, it also pushes storage device 1100 leftward, engaging storage device 1100 with communication channel 158.

While the invention has been illustrated and described in the drawings and foregoing description, such illustration and description is to be considered as exemplary and not restrictive in character. One embodiment of the invention and minor variants thereof have been shown and described. Protection is desired for all changes and modifications that come within the spirit of the invention. Those skilled in the art will appreciate variations of the above-described embodiments that fall within the scope of the invention. As a result, the invention is not limited to the specific examples and illustrations discussed above, but only by the following claims and their equivalents.

What is claimed is:

1. A storage enclosure for housing multiple storage devices, the storage enclosure comprising:
a rigid frame; and
multiple bays mounted within the frame, each bay comprising:
a body movably attached to the frame, wherein repositioning of the body with respect to the frame is restricted by at least one holding element of the frame to a limited range of motion at the enclosure,
wherein the body defines a receptacle for receiving and holding a storage device having dimensions matching a standardized form factor; and
a lever arm rotatably attached to the frame, the lever arm comprising a cam surface adapted to engage with the body of the bay and adapted to move the body with respect to the enclosure upon rotation of the lever arm,
wherein when the lever arm achieves a first rotational position, the body is adapted to engage the storage device with a communication channel of the enclosure, and
wherein when the lever arm achieves a second rotational position, the body is adapted to disengage the storage device from the communication channel.

2. The enclosure of claim 1, wherein each of the multiple bays further comprise:
a catch for securing the lever arm in the first rotational position.

3. The enclosure of claim 1, wherein each of the multiple bays further comprise:
a heat sink attached to the lever arm, the heat sink adapted to thermally couple with the storage device when the lever arm achieves the first rotational position.

4. The enclosure of claim 1, wherein, for each of the multiple bays:
the receptacle is adapted to receive the storage device without use of a tool.

5. The enclosure of claim 1, wherein, for each of the multiple bays:
the lever arm further comprises a spacing element adapted to restrain motion of the storage device within the receptacle when the lever arm achieves the first rotational position.

6. The enclosure of claim 1, wherein:
each of the multiple bays is non-removably attached to the frame.

7. The enclosure of claim 1, wherein, for each of the multiple bays:
the body of the bay is adapted to directly contact the storage device when the receptacle receives the storage device; and
the receptacle defined by the body is dimensioned to reject storage devices that are coupled to external features, the external features having dimensions not matching the standardized form factor.

8. The enclosure of claim 1, wherein:
the enclosure comprises twenty bays.

9. The enclosure of claim 1, further comprising:
multiple drawers, each drawer comprising multiple bays.

10. The enclosure of claim 1, further comprising:
a power unit adapted to provide electricity to each storage device coupled with a communication channel of the enclosure.

11. A bay for a storage system, comprising:
a body movably attached to a rigid frame of the storage system, wherein repositioning of the body with respect to the frame is restricted by at least one holding element of the frame to a limited range of motion at the rigid frame,
wherein the body defines a receptacle for receiving and holding a storage device having dimensions matching a standardized form factor; and
a lever arm rotatably attached to the frame, the lever arm comprising a cam surface adapted to engage with the body of the bay and adapted to move the body with respect to the storage system upon rotation of the lever arm,
wherein when the lever arm achieves a first rotational position, the body is adapted to engage the storage device with a communication channel of the storage system, and
wherein when the lever arm achieves a second rotational position, the body is adapted to disengage the storage device from the communication channel.

12. The bay of claim 11, wherein the bay further comprises:
a catch for securing the lever arm in the first rotational position.

13. The bay of claim 11, wherein the bay further comprises:
a heat sink attached to the lever arm, the heat sink adapted to thermally couple with the storage device when the lever arm achieves the first rotational position.

14. The bay of claim 11, wherein:
the receptacle is adapted to receive the storage device without use of a tool.

15. The bay of claim 11, wherein:
the lever arm further comprises a spacing element adapted to restrain motion of the storage device within the receptacle when the lever arm achieves the first rotational position.

16. The bay of claim 11, wherein:
the bay is non-removably attached to the frame.

17. The bay of claim 11, wherein:
the body of the bay is adapted to directly contact the storage device when the receptacle receives the storage device; and
the receptacle defined by the body is dimensioned to reject storage devices that are coupled to external features, the external features having dimensions not matching the standardized form factor.

18. A method comprising:
identifying an enclosure comprising multiple bays;
selecting a bay of the enclosure comprising a body and further comprising a lever arm rotatably attached to the frame of the enclosure, the lever arm comprising a cam surface adapted to engage with the body of the bay and move the bay with respect to the enclosure upon rotation of the lever arm,
wherein the body is movably attached to the frame, wherein repositioning of the body with respect to the frame is restricted by at least one holding element of the frame to a limited range of motion at the enclosure,
wherein the body defines a receptacle for receiving and holding a storage device having dimensions matching a standardized form factor;
placing, within the receptacle of the bay, a storage device having dimensions matching the standardized form factor; and
moving the lever arm to a first rotational position, displacing the body of the bay with respect to the enclosure, thereby engaging the storage device with a communication channel of the enclosure.

19. The method of claim 18, further comprising:
moving the lever arm to a second rotational position, thereby disengaging the storage device from the communication channel.

20. The method of claim 18, further comprising:
securing the lever arm in the first rotational position by use of a catch of the bay.
